(19) United States
(12) Patent Application Publication
(10) Pub. No.: US 2022/0131036 A1
(43) Pub. Date: Apr. 28, 2022

(54) MICRO LIGHT-EMITTING DEVICE AND DISPLAY APPARATUS THEREOF

(71) Applicant: PlayNitride Display Co., Ltd., MiaoLi County (TW)

(72) Inventors: Yu-Yun Lo, MiaoLi County (TW); Yen-Chun Tseng, MiaoLi County (TW); Yi-Chun Shih, MiaoLi County (TW); Bo-Wei Wu, MiaoLi County (TW)

(73) Assignee: PlayNitride Display Co., Ltd., MiaoLi County (TW)

(21) Appl. No.: 17/123,085

(22) Filed: Dec. 15, 2020

(30) Foreign Application Priority Data
Oct. 28, 2020 (TW) 109137406

(51) Int. Cl. H01L 33/20; H01L 25/16

(52) U.S. Cl. CPC H01L 33/20; H01L 33/385; H01L 25/167

(57) ABSTRACT

A micro light-emitting device includes an epitaxial structure, a first electrode, and a second electrode. The epitaxial structure includes a first-type semiconductor layer, a light-emitting layer, and a second-type semiconductor layer. The light-emitting layer is disposed between the first-type semiconductor layer and the second-type semiconductor layer. The first-type semiconductor layer includes a first portion and a second portion connected to each other. A distance is present between an edge of the first portion and an edge of the second portion. A bottom area of the first portion is smaller than a top area of the second portion. The first electrode is disposed on the epitaxial structure and located on the first portion of the first-type semiconductor layer. The second electrode is disposed on the epitaxial structure.

### CROSS-REFERENCE TO RELATED APPLICATION

This application claims the priority benefit of Taiwanese application serial no. 109137406, filed on Oct. 28, 2020. The entirety of the above-mentioned patent application is hereby incorporated by reference herein and made a part of this specification.

### BACKGROUND

### Technical Field

The disclosure relates to a semiconductor device; particularly, the disclosure relates to a micro light-emitting device and a micro light-emitting device display apparatus.

### Description of Related Art

Light-emitting devices, such as a light-emitting diode (LED), emit light through driving the light-emitting layer of the light-emitting diode by an electric current. At the current stage, the light-emitting diode still faces many technical challenges, and one of them is the efficiency droop effect of the light-emitting diode. Specifically, when the light-emitting diode is driven within an operating range of current density, it corresponds to a peak value of the external quantum efficiency (EQE). As the current density of the light-emitting diode continues to increase, the external quantum efficiency will decrease, and this phenomenon is the efficiency droop effect of the light-emitting diode.

Currently, when manufacturing the micro light-emitting diode (micro LED), an etching process is adopted for procedures such as mesa and isolation. However, during the etching process, sidewalls of the micro light-emitting diode may be damaged. When the size of the micro light-emitting diode is less than 50 micrometers (μm), the proportion of carriers flowing through the sidewall increases as the surface area of the sidewall accounts for an increasing proportion of the overall surface area of the epitaxial structure, which thereby affects the micro light-emitting diode, and results in a substantial decrease in the external quantum efficiency.

### SUMMARY

The disclosure provides a micro light-emitting device that improves the quantum efficiency.

The disclosure also provides a micro light-emitting device display apparatus, including the above-mentioned micro light-emitting device and has better display quality.

The micro light-emitting device of the disclosure includes an epitaxial structure, a first electrode, and a second electrode. The epitaxial structure includes a first-type semiconductor layer, a light-emitting layer, and a second-type semiconductor layer. The light-emitting layer is located between the first-type semiconductor layer and the second-type semiconductor layer. The first-type semiconductor layer includes a first portion and a second portion connected to each other. A distance is present between an edge of the first portion and an edge of the second portion. A bottom area of the first portion is smaller than a top area of the second portion. The first electrode is disposed on the epitaxial structure and located on the first portion of the first-type semiconductor layer. The second electrode is disposed on the epitaxial structure.

In an embodiment of the disclosure, in the first-type semiconductor layer, a resistance value of the first portion is greater than a resistance value of the second portion.

In an embodiment of the disclosure, a resistance value of an overlapping region between the second portion and the first portion is smaller than a resistance value of a non-overlapping region between the second portion and the first portion.

In an embodiment of the disclosure, in the first-type semiconductor layer, the first portion is of a first thickness, and the second portion is of a second thickness. A ratio of the second thickness to the first thickness is between 0.1 and 0.5.

In an embodiment of the disclosure, the second thickness of the second portion is between 0.1 μm and 0.5 μm.

In an embodiment of the disclosure, a ratio of the bottom area of the first portion to a bottom area of the first-type semiconductor layer is between 0.8 and 0.98.

In an embodiment of the disclosure, the distance is between 0.5 μm and 5 μm.

In an embodiment of the disclosure, a length of the epitaxial structure is less than or equal to 50 μm.

In an embodiment of the disclosure, a ratio of a surface area of a side surface of the epitaxial structure to a surface area of the epitaxial structure is greater than or equal to 0.01.

In an embodiment of the disclosure, a cross-sectional shape of the first portion of the first-type semiconductor layer is a trapezoid. A cross-sectional shape of the second portion of the first-type semiconductor layer, the light-emitting layer, and the second-type semiconductor layer that are stacked is a trapezoid.

In an embodiment of the disclosure, a side surface of the light-emitting layer is coplanar with a side surface of the second portion of the first-type semiconductor layer.

In an embodiment of the disclosure, the first-type semiconductor layer has a connecting surface between the first portion and the second portion. An angle between the connecting surface and a side surface of the first portion is between 30 degrees and 80 degrees.

In an embodiment of the disclosure, the second-type semiconductor layer has a bottom surface relatively away from the light-emitting layer. An angle between the bottom surface and a side surface of the second-type semiconductor layer is between 30 degrees and 80 degrees.

In an embodiment of the disclosure, a ratio of a thickness of the first portion of the first-type semiconductor layer to a thickness of the epitaxial structure is between 0.05 and 0.4. A ratio of a side surface area of the first portion to a side surface area of the epitaxial structure is between 0.2 and 0.8.

In an embodiment of the disclosure, an orthogonal projection of the first electrode on the first-type semiconductor layer is located within the first portion.

In an embodiment of the disclosure, the first-type semiconductor layer is a P-type semiconductor layer, and the second-type semiconductor layer is an N-type semiconductor layer.

In an embodiment of the disclosure, the first electrode and the second electrode are respectively located on two opposite sides of the epitaxial structure.

In an embodiment of the disclosure, the second-type semiconductor layer comprises a third portion and a fourth portion connected to each other. A cross-sectional shape of the first portion of the first-type semiconductor layer is a trapezoid. A cross-sectional shape of the second portion of the first-type semiconductor layer, the light-emitting layer, and the third portion of the second-type semiconductor layer that are stacked is a trapezoid. A cross-sectional shape of the fourth portion of the second-type semiconductor layer is a trapezoid.

In an embodiment of the disclosure, the micro light-emitting device further includes an isolating layer. The isolating layer extends to cover a peripheral surface of the first-type semiconductor layer and a peripheral surface of the light-emitting layer. The second electrode is connected to the second-type semiconductor layer and extends from the second-type semiconductor layer along a side surface of the epitaxial structure to cover the isolating layer. One end of the second electrode and the first electrode are located on the same side of the epitaxial structure.

In an embodiment of the disclosure, the epitaxial structure further includes a through hole. The through hole penetrates the first-type semiconductor layer, the light-emitting layer, and part of the second-type semiconductor layer. The micro light-emitting device further includes an isolating layer. The isolating layer is disposed on the first portion of the first-type semiconductor layer together with the first electrode and extends to cover an inner wall of the through hole and a peripheral surface of the epitaxial structure. The first electrode and the second electrode are located on the first portion of the first-type semiconductor layer. The second electrode extends into the through hole and is electrically connected to the second-type semiconductor layer.

In an embodiment of the disclosure, the micro light-emitting device further includes a current regulating layer. The current regulating layer is disposed within the second portion of the first-type semiconductor layer. The current regulating layer extends from a peripheral surface of the second portion toward an inside of the first-type semiconductor layer.

In an embodiment of the disclosure, the micro light-emitting device further includes an ohmic contact layer. The ohmic contact layer is disposed between the first portion of the first-type semiconductor layer and the first electrode.

In an embodiment of the disclosure, the micro light-emitting device further includes an isolating layer. The isolating layer is disposed on the first portion of the first-type semiconductor layer together with the first electrode, exposes part of the first portion, and extends to cover a peripheral surface of the epitaxial structure.

The micro light-emitting device display apparatus of the disclosure includes a driving substrate and a plurality of micro light-emitting devices. The micro light-emitting devices are separately disposed on the driving substrate and electrically connected to the driving substrate. The micro light-emitting device includes an epitaxial structure, a first electrode, and a second electrode. The epitaxial structure includes a first-type semiconductor layer, a light-emitting layer, and a second-type semiconductor layer. The light-emitting layer is located between the first-type semiconductor layer and the second-type semiconductor layer. The first-type semiconductor layer includes a first portion and a second portion connected to each other. A distance is present between an edge of the first portion and an edge of the second portion. The second portion is located between the first portion and the light-emitting layer. The first electrode is disposed on the epitaxial structure and located on the first portion of the first-type semiconductor layer. The second electrode is disposed on the epitaxial structure.

Based on the foregoing, in the design of the micro light-emitting device of the disclosure, the first-type semiconductor layer includes the first portion and the second portion that are connected to each other, a distance is present between the edge of the first portion and the edge of the second portion, and the bottom area of the first portion is smaller than the top area of the second portion. With this design, the thickness of the peripheral edge of the first-type semiconductor layer may be reduced to increase the thin film resistance around part of the first-type semiconductor layer, thereby reducing the proportion of the first-type semiconductor carriers moving toward the sidewall. In this way, the quantum efficiency of the micro light-emitting device of the disclosure may be improved, and the micro light-emitting device display apparatus adopting the micro light-emitting device of the disclosure may have better display quality.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic top view of a micro light-emitting device display apparatus according to an embodiment of the disclosure.

FIG. 1B is a schematic three-dimensional diagram of a micro light-emitting device of the micro light-emitting device display apparatus of FIG. 1A.

FIG. 1C is a schematic cross-sectional view of the micro light-emitting device of the micro light-emitting device display apparatus of FIG. 1A.

FIG. 2A is a schematic cross-sectional view of a micro light-emitting device according to another embodiment of the disclosure.

FIG. 2B is a schematic cross-sectional view of a micro light-emitting device according to another embodiment of the disclosure.

FIG. 3 is a schematic cross-sectional view of a micro light-emitting device according to another embodiment of the disclosure.

FIG. 4A is a schematic cross-sectional view of a micro light-emitting device according to another embodiment of the disclosure.

FIG. 4B is a schematic cross-sectional view of a micro light-emitting device according to another embodiment of the disclosure.

FIG. 4C is a schematic cross-sectional view of a micro light-emitting device according to another embodiment of the disclosure.

FIG. 5A is a curve chart of a current density and a quantum efficiency of a plurality of micro light-emitting devices having different etching depths.

FIG. 5B is a curve chart of a current density and a quantum efficiency of a plurality of micro light-emitting devices having different etching widths.

### DESCRIPTION OF THE EMBODIMENTS

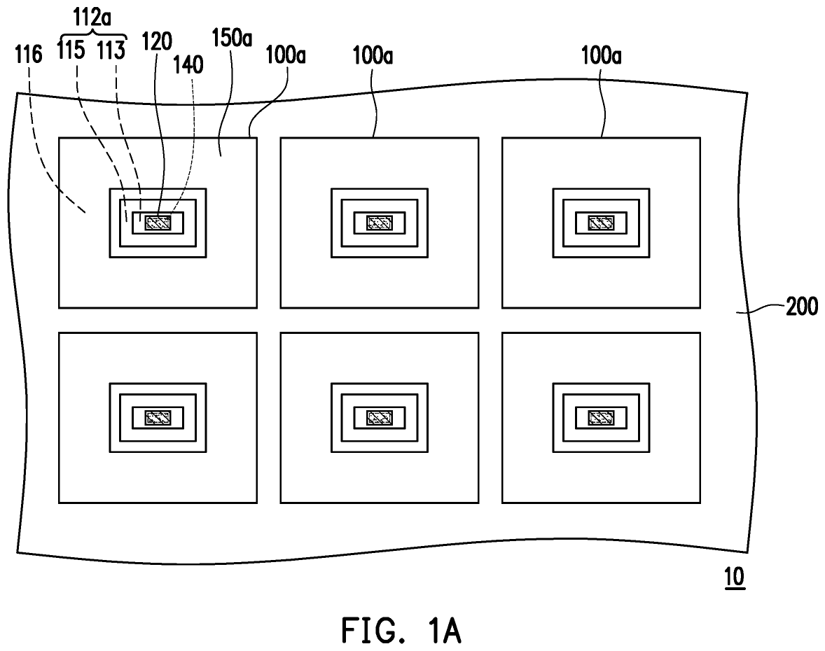

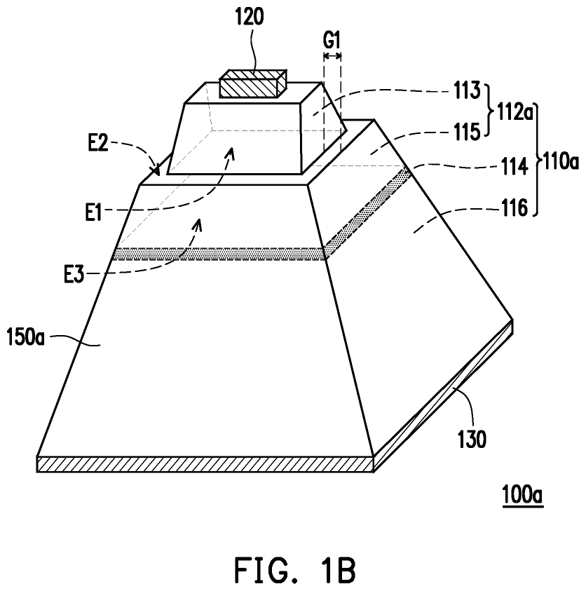

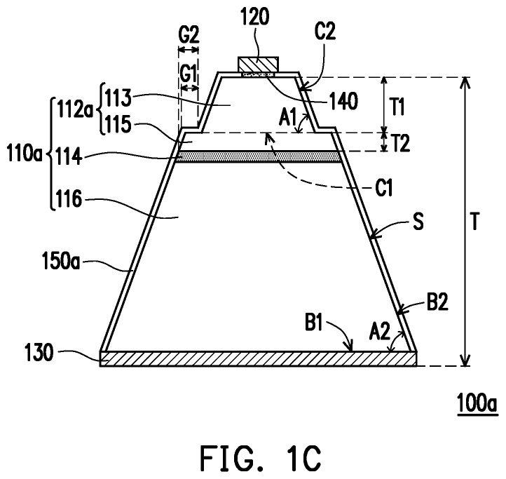

FIG. 1A is a schematic top view of a micro light-emitting device display apparatus according to an embodiment of the disclosure. FIG. 1B is a schematic three-dimensional diagram of a micro light-emitting device of the micro light-emitting device display apparatus of FIG. 1A. FIG. 1C is a schematic cross-sectional view of the micro light-emitting device of the micro light-emitting device display apparatus of FIG. 1A.

With reference to FIG. 1A first, in this embodiment, a micro light-emitting device display apparatus 10 includes a plurality of micro light-emitting devices 100a and a driving substrate 200. The micro light-emitting devices 100a are separately disposed on the driving substrate 200 and electrically connected to the driving substrate 200. Herein, the driving substrate 200 is, for example but is not limited to, a complementary metal-oxide-semiconductor (CMOS) substrate, a liquid crystal on silicon (LCOS) substrate, a thin film transistor (TFT) substrate, or any other substrate having a working circuit. The micro light-emitting device 100a is, for example, a micro light-emitting diode (Micro LED) or a microchip. The term “micro” device as used herein means that it may have a size of 1 μm to 100 μm. In some embodiments, the micro-device may have a maximum width of 20 μm, 10 μm, or 5 μm. In some embodiments, the micro-device may have a maximum height of less than 20 μm, 10 μm, or 5 μm. However, it should be understood that the embodiments of the disclosure are not necessarily limited thereto, and the aspects of some embodiments shall be applicable to a larger or possibly smaller scale.

To be specific, with reference to FIG. 1A, FIG. 1B, and FIG. 1C together, the micro light-emitting device 100a includes an epitaxial structure 110a, a first electrode 120, and a second electrode 130. The epitaxial structure 110a includes a first-type semiconductor layer 112a, a light-emitting layer 114, and a second-type semiconductor layer 116. The light-emitting layer 114 is located between the first-type semiconductor layer 112a and the second-type semiconductor layer 116. The first-type semiconductor layer 112a includes a first portion 113 and a second portion 115 connected to each other. A distance G1 is present between an edge of the first portion 113 and an edge of the second portion 115. That is, a width of the first portion 113 is different from a width of the second portion 115, and the distance G1 is the width difference between the first portion 113 and the second portion 115. The second portion 115 is located between the first portion 113 and the light-emitting layer 114. Herein, the first portion 113 and the second portion 115 are formed at the same time in the manufacturing process and are of the same material, and a bottom area E1 of the first portion 113 is smaller than a top area E2 of the second portion 115. The first electrode 120 is disposed on the epitaxial structure 110a and is located on the first portion 113 of the first-type semiconductor layer 112a. In particular, an orthogonal projection of the first electrode 120 on the first-type semiconductor layer 112a is located within the first portion 113. The second electrode 130 is disposed on the epitaxial structure 110a. In this embodiment, the first electrode 120 and the second electrode 130 are respectively located on two opposite sides of the epitaxial structure 110a. That is, the micro light-emitting device 100a may be embodied as a vertical micro light-emitting diode. The first-type semiconductor layer 112a is, for example, a P-type semiconductor layer, and the second-type semiconductor layer 116 is, for example, an N-type semiconductor layer, but they are not limited thereto.

To be specific, in the first-type semiconductor layer 112a of this embodiment, a resistance value of the first portion 113 is greater than a resistance value of the second portion 115. A resistance value of an overlapping region between the second portion 115 and the first portion 113 is smaller than a resistance value of a non-overlapping region between the second portion 115 and the first portion 113. That is to say, as shown in FIG. 1B and FIG. 1C, the resistance value of the two sides of the second portion 115 (i.e., the area not covered by the first portion 113) is greater than the resistance value of the middle (i.e., the area covered by the first portion 113) of the second portion 115. Therefore, most first-type semiconductor carriers of the first-type semiconductor layer 112a move toward the middle of the second portion 115, thereby reducing the ratio of the first-type semiconductor carriers toward a sidewall of the epitaxial structure 110a. In this way, the quantum efficiency of the micro light-emitting device 100a of this embodiment may be improved.

With reference to FIG. 1C again, in the first-type semiconductor layer 112a of this embodiment, the first portion 113 is of a first thickness T1, the second portion 115 is of a second thickness T2, and a ratio of the second thickness T2 to the first thickness T1 is, for example, between 0.1 and 0.5. Herein, the second thickness T2 of the second portion 115 is, for example, between 0.1 μm and 0.5 μm. If the second thickness T2 of the second portion 115 is too small (i.e., the above-mentioned ratio being less than 0.1), then the yield of the process will be reduced; in contrast, if the second thickness T2 of the second portion 115 is too large (i.e., the above-mentioned ratio being greater than 0.5), reduction of the first-type semiconductor carriers moving toward the sidewall cannot be achieved.

In terms of area ratio, a ratio of the bottom area E1 of the first portion 113 of the first-type semiconductor layer 112a to a bottom area E3 (i.e., a bottom area of the second portion 115) of the first-type semiconductor layer 112a is, for example, between 0.8 and 0.98. Furthermore, a ratio of a surface area of a side surface S of the epitaxial structure 110a to a surface area of the epitaxial structure 110a is, for example, greater than or equal to 0.01. Herein, a length of the epitaxial structure 110a is, for example, less than or equal to 50 μm. Moreover, in this embodiment, the distance G1 between the edge of the first portion 113 and the edge of the second portion 115 is, for example, between 0.5 μm and 5 μm. If the distance G1 is too large (i.e., greater than 5 μm), this will affect a light-emitting area of the light-emitting layer 114. Besides, a ratio of the first thickness T1 of the first portion 113 of the first-type semiconductor layer 112a to a thickness T of the epitaxial structure 110a is, for example, between 0.05 and 0.4. Through the above-mentioned ratio range, the thickness of the first portion 113 is controlled in an appropriate range, which reduces the likelihood of carriers escaping from the sidewall of the first portion 113 since the sidewall is too long, or reduces the difficulty or failure rate, among others, of the process increased due to the thickness being too small. In one embodiment, the thickness T of the epitaxial structure 110a is, for example, 3 μm to 8 μm, and the thickness (i.e., the first thickness T1 plus the second thickness T2) of the first-type semiconductor layer 112a is, for example, 0.5 μm to 1 μm. A ratio of a side surface area of the first portion 113 of the first-type semiconductor layer 112a to a side surface area of the epitaxial structure 110a is, for example, between 0.2 and 0.8. As the ratio of the side surface area of the first portion 113 is within the above-mentioned ratio range, the light-emitting area of the first-type semiconductor layer 112a and the thin film resistance effect may both be attended to. That is, this ensures a relatively large area in which the carriers pass through the light-emitting layer 114, and maintains the distance G1 between the first portion 113 and the second portion 115, so that the resistance difference between the layers is not reduced due to the distance G1 being too short.

With reference to FIG. 1C again, a cross-sectional shape of the first portion 113 of the first-type semiconductor layer 112a in this embodiment is a trapezoid. A cross-sectional shape of the second portion 115 of the first-type semiconductor layer 112a, the light-emitting layer 114, and the second-type semiconductor layer 116 that are stacked is a trapezoid. That is, the epitaxial structure 110a of this embodiment is exhibited as two trapezoids in structure, which increases the light-emitting efficiency. More specifically, a side surface of the light-emitting layer 114 is coplanar with a side surface of the second portion 115 of the first-type semiconductor layer 112a, and the plane is an inclined plane. Another distance G2 is present between the edge of the first portion 113 of the first-type semiconductor layer 112a and an edge of the light-emitting layer 114, and the another distance G2 may be slightly greater than or substantially equal to the distance G1, and is not limited herein.

Moreover, the first-type semiconductor layer 112a has a connecting surface C1 between the first portion 113 and the second portion 115, and an angle A1 between the connecting surface C1 and a side surface C2 of the first portion 113 is, for example, between 30 degrees and 80 degrees. On the other hand, the second-type semiconductor layer 116 has a bottom surface B1 relatively away from the light-emitting layer 114, and an angle A2 between the bottom surface B1 and a side surface B2 of the second-type semiconductor layer 116 is, for example, 30 degrees to 80 degrees. That is, the angle of the trapezoid is, for example, between 30 degrees and 80 degrees.

In addition, with reference to FIG. 1C again, the micro light-emitting device 100a of this embodiment further includes an ohmic contact layer 140. The ohmic contact layer 140 is disposed between the first portion 113 of the first-type semiconductor layer 112a and the first electrode 120. Since the micro light-emitting device 100a has a relatively small area, the injection efficiency and current distribution of the electron hole may be improved through the ohmic contact layer 140. Besides, the micro light-emitting device 100a of this embodiment also includes an isolating layer 150a. The isolating layer 150a is disposed on the first portion 113 of the first-type semiconductor layer 112a together with the first electrode 120, exposes part of the first portion 113, and extends to cover a peripheral surface S of the epitaxial structure 110a.

Briefly speaking, in the first-type semiconductor layer 112a of this embodiment, since the distance G1 is present between the edge of the first portion 113 and the edge of the second portion 115, the thickness of the peripheral edge of the first-type semiconductor layer 112a may be reduced to increase the thin film resistance around part of the first-type semiconductor layer 112a, thereby reducing the proportion of the first-type semiconductor carriers moving toward the sidewall. In this way, the quantum efficiency of the micro light-emitting device 100a of this embodiment may be improved, and the micro light-emitting device display apparatus 10 adopting the micro light-emitting device 100a of this embodiment may have better display quality.

It should be noted herein that the reference numerals and part of the content of the above embodiment remain to be used in the following embodiments, the same or similar reference numerals are adopted to represent the same or similar elements, and the description of the same technical content is omitted. Reference may be made to the above embodiment for the description of the omitted part, which will not be repeated in the following embodiments.

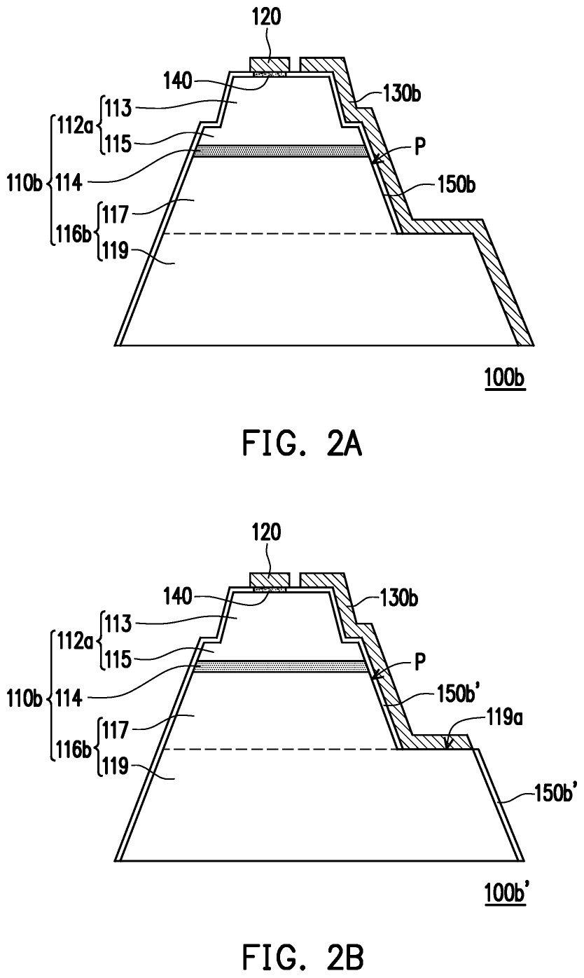

FIG. 2A is a schematic cross-sectional view of a micro light-emitting device according to another embodiment of the disclosure. With reference to FIG. 1C and FIG. 2A together, a micro light-emitting device 100b of this embodiment is similar to the micro light-emitting device 100a of FIG. 1C, and the difference between the two is that in this embodiment, a second-type semiconductor layer 116b of an epitaxial structure 110b includes a third portion 117 and a fourth portion 119 connected to each other. The cross-sectional shape of the first portion 113 of the first-type semiconductor layer 112a is a trapezoid. A cross-sectional shape of the second portion 115 of the first-type semiconductor layer 112a, the light-emitting layer 114, and the third portion 117 of the second-type semiconductor layer 116b that are stacked is a trapezoid. A cross-sectional shape of the fourth portion 119 of the second-type semiconductor layer 116b is a trapezoid. That is to say, the epitaxial structure 110b of this embodiment is exhibited as three trapezoids in structure. Moreover, an isolating layer 150b of this embodiment extends to cover the peripheral surface of the first-type semiconductor layer 112a and the peripheral surface of the light-emitting layer 114. To be specific, the isolating layer 150b is disposed on the first portion 113 of the first-type semiconductor layer 112a together with the first electrode 120, and extends to cover the peripheral surface of the first-type semiconductor layer 112a, the peripheral surface of the light-emitting layer 114, and the peripheral surface of the third portion 117 and part of the peripheral surface of the fourth portion 119 of the second-type semiconductor layer 116b. That is, the isolating layer 150b exposes part of the fourth portion 119 of the second-type semiconductor layer 116b. Also, as shown in a micro light-emitting device 100b′ of FIG. 2B, an isolating layer 150b′ may also completely cover a side surface of the fourth portion 119, and expose merely part of a top surface 119a of the fourth portion 119 configured to contact a second electrode 130b. The first electrode 120 and the second electrode 130b may be located on the same side of the epitaxial structure 110b. That is, the micro light-emitting device 100b may be a flip-chip type or a lateral type light-emitting diode. In FIG. 2A and FIG. 2B, the second electrode 130b is connected to the second-type semiconductor layer 116b and extends from the second-type semiconductor layer 116b along a side surface P of the epitaxial structure 110b to cover the isolating layer 150b, and one end of the second electrode 130b and the first electrode 120 are located on the same side of the epitaxial structure 110b. Furthermore, the second electrode 130b extends from the first portion 113 of the first-type semiconductor layer 112a along the side surface P of the epitaxial structure 110b to a region of the fourth portion 119 of the second-type semiconductor layer 116b not covered by the isolating layer 150b, and is electrically connected to the fourth portion 119. Due to the structural design of the epitaxial structure 110b of this embodiment, the first electrode 120 and the second electrode 130b are of the same height, and thus may have a better configuration yield.

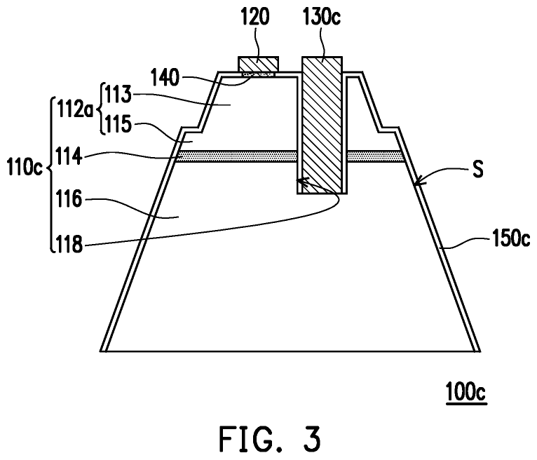

FIG. 3 is a schematic cross-sectional view of a micro light-emitting device according to another embodiment of the disclosure. With reference to FIG. 1C and FIG. 3 together, a micro light-emitting device 100c of this embodiment is similar to the micro light-emitting device 100a of FIG. 1C, and the difference between the two is that in this embodiment, an epitaxial structure 110c further includes a through hole 118, the through hole 118 penetrates the first-type semiconductor layer 112a, the light-emitting layer 114, and part of the second-type semiconductor layer 116. In addition, in the micro light-emitting device 100c, an isolating layer 150c is disposed on the first portion 113 of the first-type semiconductor layer 112a together with the first electrode 120, and extends to cover an inner wall of the through hole 118 and the peripheral surface of the epitaxial structure 110c. Moreover, the first electrode 120 and a second electrode 130c are located on the first portion 113 of the first-type semiconductor layer 112a, and the second electrode 130c extends into the through hole 118 and is electrically connected to the second-type semiconductor layer 116.

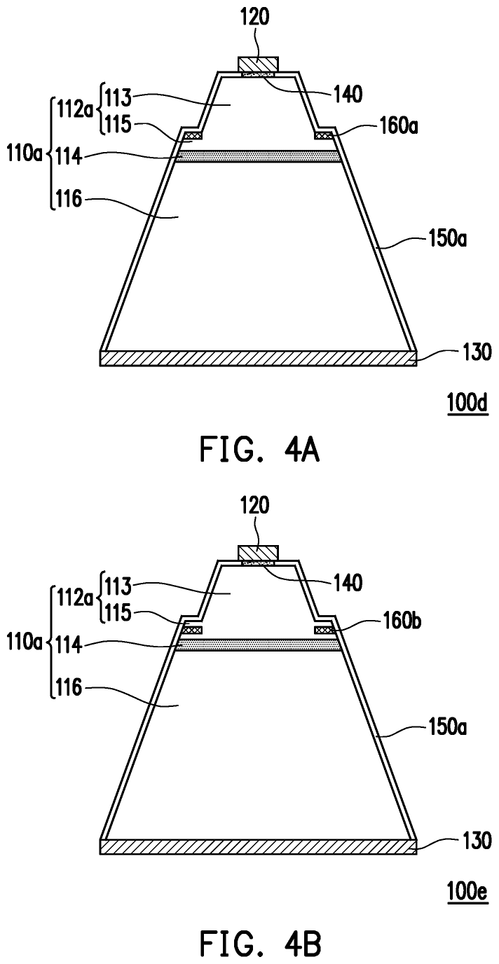

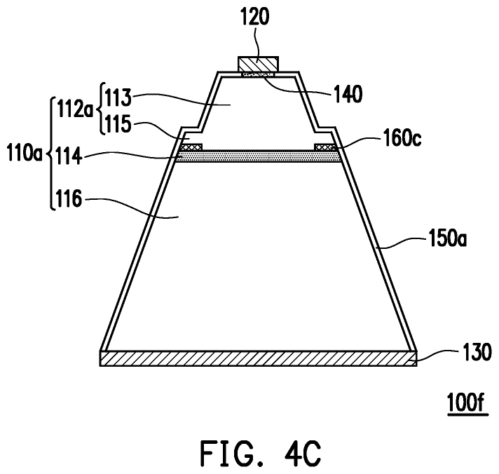

FIG. 4A is a schematic cross-sectional view of a micro light-emitting device according to another embodiment of the disclosure. With reference to FIG. 1C and FIG. 4A together, a micro light-emitting device 100d of this embodiment is similar to the micro light-emitting device 100a of FIG. 1C, and the difference between the two is that in this embodiment, the micro light-emitting device 100d further includes a current regulating layer 160a, and the current regulating layer 160a is disposed within the second portion 115 of the first-type semiconductor layer 112a. As shown in FIG. 4A, the current regulating layer 160a extends from a peripheral surface of the second portion 115 toward an inside of the first-type semiconductor layer 112a, and the current regulating layer 160a is located relatively adjacent to the first portion 113 of the first-type semiconductor layer 112a. Herein, the material of the current regulating layer 160a is, for example, a non-conductive insulating material, such as silicon dioxide (SiO₂) or aluminum nitride (AlN).

FIG. 4B is a schematic cross-sectional view of a micro light-emitting device according to another embodiment of the disclosure. With reference to FIG. 4A and FIG. 4B together, a micro light-emitting device 100e of this embodiment is similar to the micro light-emitting device 100d of FIG. 4A, and the difference between the two is that in this embodiment, a current regulating layer 160b is located at the middle of the second portion 115 of the first-type semiconductor layer 112a.

FIG. 4C is a schematic cross-sectional view of a micro light-emitting device according to another embodiment of the disclosure. With reference to FIG. 4A and FIG. 4C together, a micro light-emitting device 100f of this embodiment is similar to the micro light-emitting device 100d of FIG. 4A, and the difference between the two is that in this embodiment, a current regulating layer 160c is located within the second portion 115 of the first-type semiconductor layer 112a and relatively adjacent to the light-emitting layer 114, which effectively prevents the first-type semiconductor carriers from moving toward a sidewall of the light-emitting layer 114.

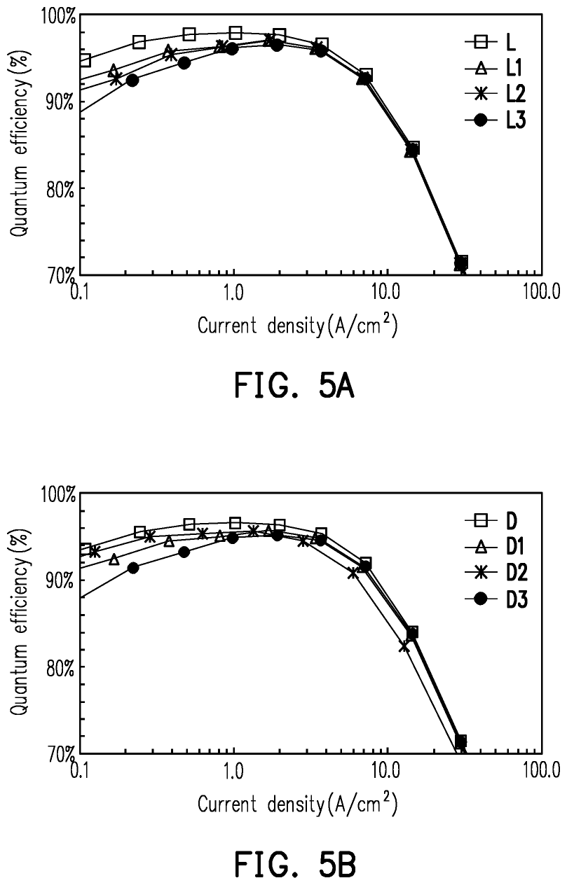

FIG. 5A is a curve chart of a current density and a quantum efficiency of a plurality of micro light-emitting devices having different etching depths. FIG. 5B is a curve chart of a current density and a quantum efficiency of a plurality of micro light-emitting devices having different etching widths. It should be noted that the etching depth described herein is, for example as shown in FIG. 1C, the second thickness T2 of the second portion 115 of the first-type semiconductor layer 112a divided by the thickness (i.e., the first thickness T1 plus T2) of the first-type semiconductor layer 112a. The etching width described herein is, for example as shown in FIG. 1C, the distance from an edge of the first electrode 120 to the edge of the first portion 113 of the first-type semiconductor layer 112a divided by the distance from the edge of the first electrode 120 to the edge of the second portion 115 of the first-type semiconductor layer 112a.

With reference to FIG. 5A, curved line L represents an ideal state where surface recombination is not considered. Curved lines L1 and L2 both include surface recombination and respectively represent states where a ratio of the etching depth is 0 and 0.12. In addition, curved line L3 includes surface recombination but a first-type semiconductor layer thereof is not patterned, so a ratio of the etching depth is 1. It is evident from FIG. 5A that as the etching depth increases (i.e., curved line L1), the quantum efficiency of the micro light-emitting device is increasingly improved.

With reference to FIG. 5B, curved line D represents an ideal state where surface recombination is not considered. Curved lines D1 and D2 both include surface recombination and respectively represent states where a ratio of the etching width is 0.33 and 0.07. In addition, curve line D3 includes surface recombination but a first-type semiconductor layer thereof is not patterned, so a ratio of the etching width is 1. It is evident from FIG. 5B that as the etching width (i.e., curve line D2) increases, the quantum efficiency of the micro light-emitting device is increasingly improved. Briefly speaking, the above-mentioned design is adapted for a small current density. For example, when the current density is less than or equal to 10 A/cm², the effect is more obvious.

In summary of the foregoing, in the design of the micro light-emitting device of the disclosure, the first-type semiconductor layer includes the first portion and the second portion that are connected to each other, and a distance is present between the edge of the first portion and the edge of the second portion. With this design, the thickness of the peripheral edge of the first-type semiconductor layer may be reduced to increase the thin film resistance around part of the first-type semiconductor layer, thereby reducing the proportion of the first-type semiconductor carriers moving toward the sidewall. In this way, the quantum efficiency of the micro light-emitting device of the disclosure may be improved, and the micro light-emitting device display apparatus adopting the micro light-emitting device of the disclosure may have better display quality.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A micro light-emitting device, comprising:
an epitaxial structure comprising a first-type semiconductor layer, a light-emitting layer, and a second-type semiconductor layer, wherein the light-emitting layer is located between the first-type semiconductor layer and the second-type semiconductor layer, the first-type semiconductor layer comprises a first portion and a second portion connected to each other, a distance is present between an edge of the first portion and an edge of the second portion, and a bottom area of the first portion is smaller than a top area of the second portion;
a first electrode disposed on the epitaxial structure and located on the first portion of the first-type semiconductor layer; and
a second electrode disposed on the epitaxial structure.

2. The micro light-emitting device according to claim 1, wherein in the first-type semiconductor layer, a resistance value of the first portion is greater than a resistance value of the second portion.

3. The micro light-emitting device according to claim 2, wherein a resistance value of an overlapping region between the second portion and the first portion is smaller than a resistance value of a non-overlapping region between the second portion and the first portion.

4. The micro light-emitting device according to claim 1, wherein in the first-type semiconductor layer, the first portion is of a first thickness, the second portion is of a second thickness, and a ratio of the second thickness to the first thickness is between 0.1 and 0.5.

5. The micro light-emitting device according to claim 4, wherein the second thickness of the second portion is between 0.1 μm and 0.5 μm.

6. The micro light-emitting device according to claim 1, wherein a ratio of the bottom area of the first portion to a bottom area of the first-type semiconductor layer is between 0.8 and 0.98.

7. The micro light-emitting device according to claim 1, wherein the distance is between 0.5 μm and 5 μm.

8. The micro light-emitting device according to claim 1, wherein a ratio of a surface area of a side surface of the epitaxial structure to a surface area of the epitaxial structure is greater than or equal to 0.01.

9. The micro light-emitting device according to claim 1, wherein a cross-sectional shape of the first portion of the first-type semiconductor layer is a trapezoid, and a cross-sectional shape of the second portion of the first-type semiconductor layer, the light-emitting layer, and the second-type semiconductor layer that are stacked is a trapezoid.

10. The micro light-emitting device according to claim 9, wherein a side surface of the light-emitting layer is coplanar with a side surface of the second portion of the first-type semiconductor layer.

11. The micro light-emitting device according to claim 9, wherein the first-type semiconductor layer has a connecting surface between the first portion and the second portion, and an angle between the connecting surface and a side surface of the first portion is between 30 degrees and 80 degrees.

12. The micro light-emitting device according to claim 9, wherein the second-type semiconductor layer has a bottom surface relatively away from the light-emitting layer, and an angle between the bottom surface and a side surface of the second-type semiconductor layer is between 30 degrees and 80 degrees.

13. The micro light-emitting device according to claim 1, wherein a ratio of a thickness of the first portion of the first-type semiconductor layer to a thickness of the epitaxial structure is between 0.05 and 0.4, and a ratio of a side surface area of the first portion to a side surface area of the epitaxial structure is between 0.2 and 0.8.

14. The micro light-emitting device according to claim 1, wherein an orthogonal projection of the first electrode on the first-type semiconductor layer is located within the first portion.

15. The micro light-emitting device according to claim 1, wherein the first electrode and the second electrode are respectively located on two opposite sides of the epitaxial structure.

16. The micro light-emitting device according to claim 1, wherein the second-type semiconductor layer comprises a third portion and a fourth portion connected to each other, a cross-sectional shape of the first portion of the first-type semiconductor layer is a trapezoid, a cross-sectional shape of the second portion of the first-type semiconductor layer, the light-emitting layer, and the third portion of the second-type semiconductor layer that are stacked is a trapezoid, and a cross-sectional shape of the fourth portion of the second-type semiconductor layer is a trapezoid.

17. The micro light-emitting device according to claim 16, further comprising:
an isolating layer extending to cover a peripheral surface of the first-type semiconductor layer and a peripheral surface of the light-emitting layer, wherein the second electrode is connected to the second-type semiconductor layer and extends from the second-type semiconductor layer along a side surface of the epitaxial structure to cover the isolating layer, and one end of the second electrode and the first electrode are located on the same side of the epitaxial structure.

18. The micro light-emitting device according to claim 1, wherein the epitaxial structure further comprises a through hole penetrating the first-type semiconductor layer, the light-emitting layer, and part of the second-type semiconductor layer, and the micro light-emitting device further comprises:
an isolating layer disposed on the first portion of the first-type semiconductor layer together with the first electrode and extending to cover an inner wall of the through hole and a peripheral surface of the epitaxial structure, wherein the first electrode and the second electrode are located on the first portion of the first-type semiconductor layer, and the second electrode extends into the through hole and is electrically connected to the second-type semiconductor layer.

19. The micro light-emitting device according to claim 1, further comprising:
a current regulating layer disposed within the second portion of the first-type semiconductor layer, wherein the current regulating layer extends from a peripheral surface of the second portion toward an inside of the first-type semiconductor layer.

20. A micro light-emitting device display apparatus, comprising:
a driving substrate; and
a plurality of the micro light-emitting devices according to claim 1, wherein the plurality of micro light-emitting devices are separately disposed on the driving substrate and electrically connected to the driving substrate.
